(19) United States
(12) Patent Application Publication
(10) Pub. No.: US 2025/0343552 A1
(43) Pub. Date: Nov. 6, 2025

(54) PLL Phase Detector/Charge Pump Linearization

(71) Applicant: Telefonaktiebolaget LM Ericsson (publ), Stockholm (SE)

(72) Inventor: Staffan Ek, Lund (SE)

(21) Appl. No.: 18/868,553

(22) PCT Filed: Jun. 2, 2022
(86) PCT No.: PCT/EP2022/065086

§ 371 Date: Nov. 22, 2024

(51) Int. Cl. H03L 7/099; H03K 5/00; H04L 7/00; H04L 7/033

(52) U.S. Cl. CPC H03L 7/099; H03K 5/00006; H04L 7/0037; H04L 7/0331; H03K 2005/00078

(57) ABSTRACT

A dual path PLL provides excellent output phase stability over PVT variations, without implementing a high accuracy TDC. A digital integral path employs a binary phase detector, comparing the reference and feedback signals, and an integrator to generate an oscillator control input to lock the long-term output phase to the reference signal. An analog proportional path employs a linear (e.g., edge triggered) phase detector and a charge pump and filter to generate an oscillator control input to mitigate phase noise in the output signal. The feedback signal to the proportional path is delayed, which has the effect of increasing the width of phase error pulses, and moving the charge pump operating point away from the zero point where it generates both positive and negative currents, which are difficult to match. A second linear phase detector in the proportional path compensates for the increased phase error pulse width by comparing the delayed and non-delayed feedback signals, and generating pulses in the opposite direction.

### TECHNICAL FIELD

The present invention relates generally to Phase Locked Loop (PLL) circuits, and in particular to a hybrid analog and digital PLL having delayed feedback to bias a phase detector and charge pump circuit to operate in a linear region.

### BACKGROUND

Wireless communications are ubiquitous in modern life. Wireless communication networks connect devices, such as smartphones, machines, and vehicles, to controllers and the vast resources of the Internet. Local wireless networks, such as Wi-Fi, connect computers, televisions, appliances, and light bulbs in homes and businesses. Ad hoc wireless links, such as Bluetooth® connect headsets with telephones, music players, and more. Most of these wireless communications operate by modulating data onto Radio Frequency (RF) electromagnetic waves, and transmitting and receiving these waves through antennas.

RF transceiver circuits require reliable, accurate, agile, and inexpensive local frequency sources to accurately frequency-convert, modulate, demodulate, and beamform RF signals. For example, RF transceivers typically require a Local Oscillator (LO) signal to down-convert a received signal from the carrier frequency to baseband (and vice versa for a transmitted signal). Systems that employ frequency hopping require that the LO signal be quickly and accurately adjustable. Directional antennas use precise phase shifts between RF signals transmitted from large arrays of antenna elements to steer the transmitted RF beam, or to enhance reception in specific directions.

Typically, an LO signal is generated using a phase locked loop (PLL). A PLL is a well-known circuit, in which a Controlled Oscillator (i.e., an analog Voltage Controlled Oscillator, VCO, or Digital Controlled Oscillator, DCO) generates a high-frequency periodic signal, such as an LO signal. The generated periodic signal is at a frequency that is a predetermined multiple of a reference signal, such as a clock signal from a crystal oscillator or other accurate source. In a feedback loop within the PLL, a Phase Detector compares a frequency-divided version of the VCO/DCO output signal with the reference signal, to generate an error signal indicative of phase deviation. The error signal is processed by a loop filter, providing an input to the VCO/DCO that keeps the output signal phase-locked to the reference signal. The output frequency of the PLL may be changed by changing frequency of the reference signal input, or by adjusting the divisor in the frequency division circuit.

As indicated above, a PLL may operate in the analog or digital domain. Advantages of a digital PLL include the absence of large area capacitors in the analog loop filter, and the possibility to support advanced digital algorithms, such as to implement high-speed frequency hops. On the other hand, advantages of an analog PLL include reduced design complexity and excellent phase noise, particularly in applications where the digital PLL in-band phase noise dominates the Error Vector Magnitude (EVM) or Signal to Noise Ratio (SNR). As one example of the design trade-offs, the simplicity of an analog PLL makes it an excellent choice at very high frequencies or for very low power. However, this choice sacrifices the possibility for digital algorithms to achieve improved performance. Regardless of the PLL architecture selected, however, a key concern is achieving sufficiently low phase noise, with limited power consumption and chip area, without sacrificing performance in other aspects.

The operation of a type-II PLL (that is, one whose transfer function has exactly one pole at the origin) can be divided into two main functions. The first is to provide an output with accurate long-term tracking of the reference phase, and the second is to detect and compensate for short term phase fluctuations at the output (e.g., oscillator phase noise) in a timely manner. The first function is achieved through integration of the phase error over a large number of reference clock periods, whereas the second function may be achieved through a proportional path, correcting the oscillator frequency based on the last detected phase error.

FIG. 1 depicts one known approach, as described by Daniel Friedman in the Presentation Hybrid PLL Architectures and Implementations, IBM Research-IEEE SSCS DL, Sep. 26, 2019, the disclosure of which is incorporated herein by reference in its entirety. This architecture divides these two functions into two paths, where each path is optimized to achieve its purpose. A digital integration path achieves long term phase tracking, such as by creating a digital control word, using digital signal processing techniques. This path may be driven by a simple binary phase detector, and the digitalization enables the implementation of large time constants. An analog proportional path achieves phase correction using an analog phase detector outputting a pulse width modulated signal. This path provides simplicity and the high linearity necessary to avoid noise folding.

In a multiple-PLL system, such as in a multi-antenna transceiver with local LO generation (e.g., as used in advanced wireless communication equipment), the phase relationship between PLLs should be well defined. Relative phase drift will naturally occur, due to temperature gradients affecting LO distribution buffers, and the like. However, if the PLLs are implemented using analog charge pumps, the phase stability is worsened due to, e.g., temperature dependent leakage currents. For the multi-antenna system to work, frequent calibrations of the PLLs are required, which limits throughput.

Phase stability may be increased by employing an implementation where the phase error is digitized. In this case, drift introduced in the signal processing chain is not affected by ambient conditions. However, for fractional-N operation, the conventional digital PLL implementation requires a high-resolution time-to-digital converter (TDC), which may introduce spurious tones in the PLL output spectrum, due to non-linear transfer as well as increased in-band noise floor due to limited resolution and long delay lines. The DPLL TDC often dominates the contribution to EVM, and severely limits channel capacity. Use of a TDC thus complicates PLL system design.

FIG. 2 depicts one implementation of the dual-path hybrid PLL architecture of FIG. 1. This offers a way to implement fractional-N operation with low phase drift, and without the need to implement a complex TDC. However, to achieve low in-band phase noise levels, the combination of phase frequency detector (PFD) and charge pump in the proportional path requires a highly linear transfer from phase error to output charge. This means that, in the general case where both negative and positive phase errors are detected during operation, a PMOS current must match an NMOS current, which is difficult to achieve in the face of process, voltage, and temperature (PVT) variations. Known solutions to this problem are complex and rely on signal processing in both analog and digital domains.

The Background section of this document is provided to place aspects of the present disclosure in technological and operational context, to assist those of skill in the art in understanding their scope and utility. Approaches described in the Background section could be pursued, but are not necessarily approaches that have been previously conceived or pursued. Unless explicitly identified as such, no statement herein is admitted to be prior art merely by its inclusion in the Background section.

### SUMMARY

The following presents a simplified summary of the disclosure in order to provide a basic understanding to those of skill in the art. This summary is not an extensive overview of the disclosure and is not intended to identify key/critical elements of embodiments of the invention or to delineate the scope of the invention. The sole purpose of this summary is to present some concepts disclosed herein in a simplified form as a prelude to the more detailed description that is presented later.

According to aspects of the present disclosure, a dual path PLL provides excellent output phase stability over PVT variations, without implementing a high accuracy TDC. The two paths are each implemented using the technology—i.e., digital or analog-best suited for their respective tasks. A digital integral path of circuitry employs a binary phase detector (acting as a digitizer) comparing the reference and feedback signals, to generate input to an integrator, which in turn generates a frequency control input to a controlled oscillator. The integral path ensures a well-defined output phase of the controlled oscillator. An analog proportional path of circuitry employs an edge triggered detector (e.g., a tristate PFD), and corrects higher frequency phase fluctuations at the PLL output, also through an oscillator frequency control input. Because the integral path ensures zero phase error, on average, between the reference and feedback signals, a first edge triggered phase detector in the proportional path sees both positive and negative phase errors, forcing the charge pump to switch between positive and negative currents, where PVT variations make it difficult to match them. To move the first edge triggered phase detector from this operating point, the feedback signal to the proportional path is delayed—effectively increasing the width of each generated phase error pulse by a constant amount. A second edge triggered phase detector in the proportional path compensates for this increased pulse width by comparing the delayed and non-delayed feedback signals, and generating phase error pulses in the opposite direction, of equal width to that added by the delay at the first edge triggered phase detector. The two edge triggered phase detector outputs are added together to generate a proportional oscillator frequency control input. The outputs of the integral and proportional paths are then added and input to the oscillator (or the oscillator may have multiple frequency control inputs).

One aspect relates to dual path Phase Locked Loop (PLL) circuit configured to minimize phase error between a periodic output signal and a reference signal. A controlled oscillator circuit is configured to generate the periodic output signal in response to frequency control inputs. A frequency divider circuit is configured to divide the periodic output signal by a divisor to generate a non-delayed feedback signal. A delay circuit is configured to delay the non-delayed feedback signal and generate a delayed feedback signal. An integral path of circuitry is configured to receive the periodic reference signal and the non-delayed feedback signal, and to generate a first frequency control signal for the controlled oscillator based on a phase difference between the periodic reference signal and the non-delayed feedback signal, so as to lock the phase of the periodic output signal to the phase of the reference signal. A proportional path of circuitry is configured to receive the periodic reference signal and the delayed feedback signal, and to generate a second frequency control signal for the controlled oscillator based on a phase difference between the periodic reference signal and the delayed feedback signal.

Another aspect relates to a dual path Phase Locked Loop (PLL) circuit configured to minimize phase error between a periodic output signal and a reference signal. A controlled oscillator circuit is configured to generate the periodic output signal in response to frequency control inputs, a frequency divider circuit is configured to divide the periodic output signal by a divisor to generate a feedback signal. An integral path of circuitry is configured to receive the periodic reference signal and one of the feedback signal and a timing-skewed feedback signal, and to generate a first frequency control signal for the controlled oscillator based on a phase difference between the periodic reference signal and the non-delayed feedback signal, so as to lock the phase of the periodic output signal to the phase of the reference signal. The integral path of circuitry comprises a binary phase detector. A proportional path of circuitry is configured to receive the periodic reference signal and one of the feedback signal and the timing-skewed feedback signal, and to generate a second frequency control signal for the controlled oscillator based on a phase difference between the periodic reference signal and the delayed feedback signal. The proportional path of circuitry comprises a linear phase detector; a charge pump connected to an output of the linear phase detector; a filter connected to the output of the charge pump and configured to output a proportional frequency correction signal to the controlled oscillator; a low pass filter connected across a terminal resistor of the filter; a comparator connected to the low pass filter and configured to output a binary indication of a polarity of a low-pass filtered voltage across the terminal resistor of the filter; and a control circuit configured to generate a timing skew control signal in response to the binary indication of polarity. The control circuit is configured to strive for zero voltage across the terminal resistor of the filter. The tinning skew control signal is either added to the output of the binary phase detector, or controls an incremental delay added by a timing skew circuit to the feedback signal input to the linear phase detector.

Yet another aspect relates to a method, in a dual path PLL comprising a controlled oscillator configured to generate a periodic output signal in response to frequency control inputs, of generating a periodic output signal. An integral path of circuitry is operated. The integral path comprises a binary phase detector circuit configured to compare a phase of a reference signal with a phase of a divided periodic output signal. The integral path integrates the result to generate a first frequency control input to the controlled oscillator 12 based on a phase difference between the periodic reference signal and the non-delayed feedback signal, so as to lock the periodic output signal phase to the reference signal phase. A proportional path of circuitry is also operated. The proportional path comprises a first linear phase detector circuit configured to compare the phase of the reference signal with a phase of a delayed, divided periodic output signal, and output phase error pulses to a charge pump circuit and filter circuit to generate a second frequency control input to the controlled oscillator based on a phase difference between the periodic reference signal and the delayed feedback signal. The delay of the delayed, divided periodic output signal increases a width of phase error pulses output by the linear phase detector, such that the charge pump circuit provides only positive or negative current to the filter circuit.

Still another aspect relates to a base station operative in a wireless communication network. The base station includes processing circuitry and transceiver circuitry operatively connected to the processing circuitry. The transceiver circuitry includes at least one dual path PLL configured to minimize phase error between a periodic output signal and a reference signal. The PLL includes a controlled oscillator circuit configured to generate a periodic output signal in response to frequency control inputs; a frequency divider circuit configured to divide the periodic output signal by a divisor to generate a non-delayed feedback signal; a delay circuit configured to delay the non-delayed feedback signal and generate a delayed feedback signal; an integral path of circuitry configured to receive the periodic reference signal and the non-delayed feedback signal, and to generate a first frequency control signal for the controlled oscillator based on a phase difference between the periodic reference signal and the non-delayed feedback signal, so as to lock the phase of the periodic output signal to the phase of the reference signal; and a proportional path of circuitry configured to receive the periodic reference signal and the delayed feedback signal, and to generate a second frequency control signal for the controlled oscillator based on a phase difference between the periodic reference signal and the delayed feedback signal.

Still another aspect relates to a User Equipment (UE) operative in a wireless communication network. The UE includes processing circuitry and transceiver circuitry operatively connected to the processing circuitry. The transceiver circuitry includes at least one dual path PLL configured to minimize phase error between a periodic output signal and a reference signal. The PLL includes a controlled oscillator circuit configured to generate the periodic output signal in response to frequency control inputs; a frequency divider circuit configured to divide the periodic output signal by a divisor to generate a non-delayed feedback signal; a delay circuit configured to delay the non-delayed feedback signal and generate a delayed feedback signal; an integral path of circuitry configured to receive the periodic reference signal and the non-delayed feedback signal, and to generate a first frequency control signal for the controlled oscillator based on a phase difference between the periodic reference signal and the non-delayed feedback signal, so as to lock the phase of the periodic output signal to the phase of the reference signal; and a proportional path of circuitry configured to receive the periodic reference signal and the delayed feedback signal, and to generate a second frequency control signal for the controlled oscillator based on a phase difference between the periodic reference signal and the delayed feedback signal.

### BRIEF DESCRIPTION OF THE DRAWINGS

The present invention will now be described more fully hereinafter with reference to the accompanying drawings, in which aspects of the disclosure are shown. However, this invention should not be construed as limited to the aspects set forth herein. Rather, these aspects are provided so that this disclosure will be thorough and complete, and will fully convey the scope of the invention to those skilled in the art. Like numbers refer to like elements throughout.

FIG. 1 is a block diagram of one known hybrid PLL architecture.

FIG. 2 is a circuit diagram of an implementation of the PLL architecture of FIG. 1.

FIG. 3 is a phase noise plot of a simulation of the circuit of FIG. 2 with no charge pump current mismatch.

FIG. 4 is a phase noise plot of a simulation of the circuit of FIG. 2 with a 10% charge pump current mismatch.

FIG. 5 is a circuit diagram of a dual path PLL using a delay on the feedback signal to the proportional path to linearize the phase error to proportional correction transfer.

FIG. 6 is a phase noise plot of a simulation of the circuit of FIG. 5 with a 10% charge pump current mismatch.

FIG. 7 is a graph of various signals of the circuit of FIG. 5.

FIG. 8 is a block diagram of a dual path PLL using a delay on the feedback signal and a second linear phase detector in the proportional path for phase error pulse width correction.

FIG. 9 is a circuit diagram of an implementation of the PLL block diagram of FIG. 8.

FIG. 10 is a graph of various signals of the circuit of FIG. 8.

FIG. 11 is a phase noise plot of a simulation of the circuit of FIG. 8 with a 10% charge pump current mismatch.

FIG. 12 is a circuit diagram of an implementation of the first linear phase detector of FIG. 8.

FIG. 13 is a circuit diagram of an implementation of the second linear phase detector of FIG. 8.

FIG. 14 is a phase noise plot of a simulation of the circuit of FIG. 8 with a 10% charge pump current mismatch, using the second linear phase detector of FIG. 13 with an additional feedback signal delay.

FIG. 15 is a circuit diagram of a dual path PLL with a timing skew circuit to match the integral and proportional paths.

FIG. 16 is a circuit diagram of a dual path PLL with a timing skew circuit in the proportional path.

FIG. 17 depicts graphs of various signals in the circuit of FIG. 16.

FIG. 18 is a circuit diagram of a dual path PLL with a timing skew applied in the integral path.

FIG. 19 depicts graphs of various signals in the circuit of FIG. 18.

FIG. 20 is a phase noise plot of a simulation of the circuit of FIG. 18 with a 10% charge pump current mismatch and the timing skew circuits inactive.

FIG. 21 is a phase noise plot of a simulation of the circuit of FIG. 18 with a 10% charge pump current mismatch and the timing skew circuits are active.

FIG. 22 is a flow diagram of a method of operating a dual path PLL circuit.

FIG. 23A depicts a UE and base station of a wireless communication network.

FIG. 23B is a block diagram of the UE of FIG. 23A.

FIG. 23C is a block diagram of the base station of FIG. 23A.

### DETAILED DESCRIPTION

For simplicity and illustrative purposes, the present disclosure is described by referring mainly to one or more exemplary aspects thereof. In the following description, numerous specific details are set forth in order to provide a thorough understanding of the present disclosure. However, it will be readily apparent to one of ordinary skill in the art that the present disclosure may be practiced without limitation to these specific details. In this description, well known methods and structures have not been described in detail so as not to unnecessarily obscure the present disclosure.

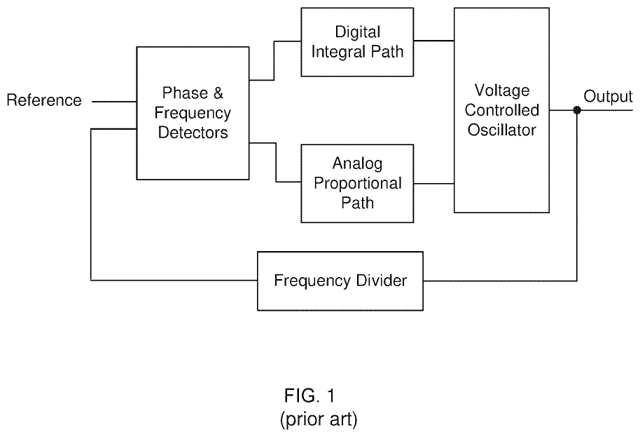

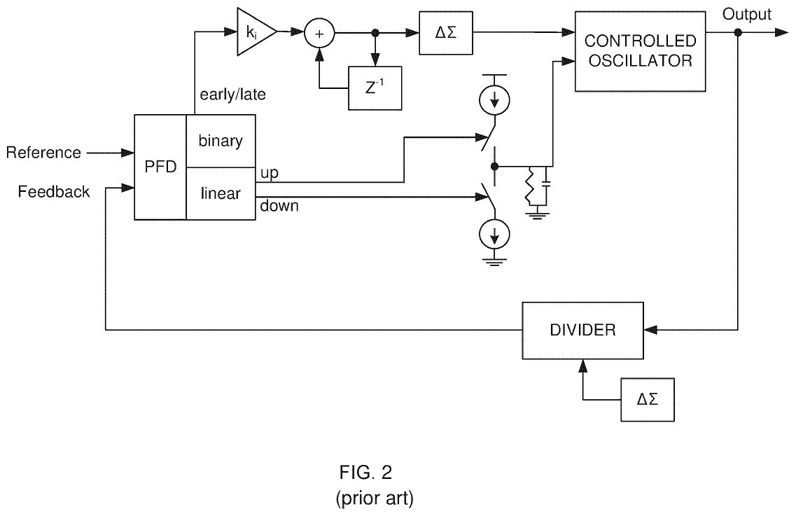

FIG. 2 depicts an implementation of the prior art, dual path PLL of FIG. 1. A Phase Frequency Detector (PFD) receives a reference signal and a divided feedback signal. The PFD is shown as two PFDs, a binary phase detector for the digital integral loop, and a linear (e.g., edge-triggered) PFD for the analog proportional loop. Although the phase detectors for the two paths are separate circuits within the PFD, they receive the same reference and feedback signals. In other implementations, the same PFD may output both digital integral and analog proportional control signals. This circuit was simulated using CPP-sim, and the simulation results are used as a baseline to demonstrate features and benefits of aspects of the present disclosure.

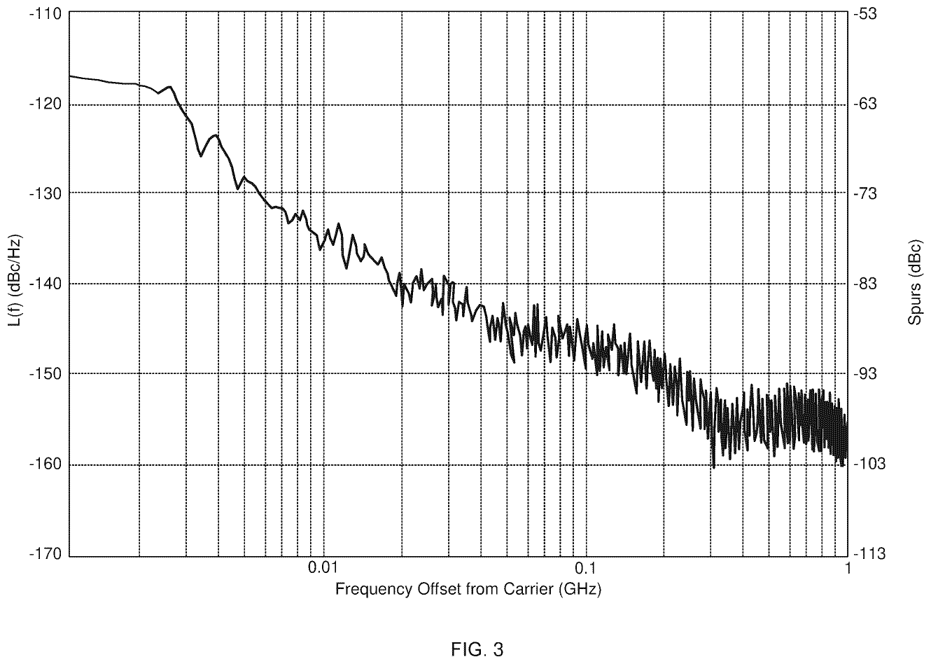

FIG. 3 is a graph of the phase noise L of this simulated circuit with matched up and down currents of the charge pump (that is, the ideal case).

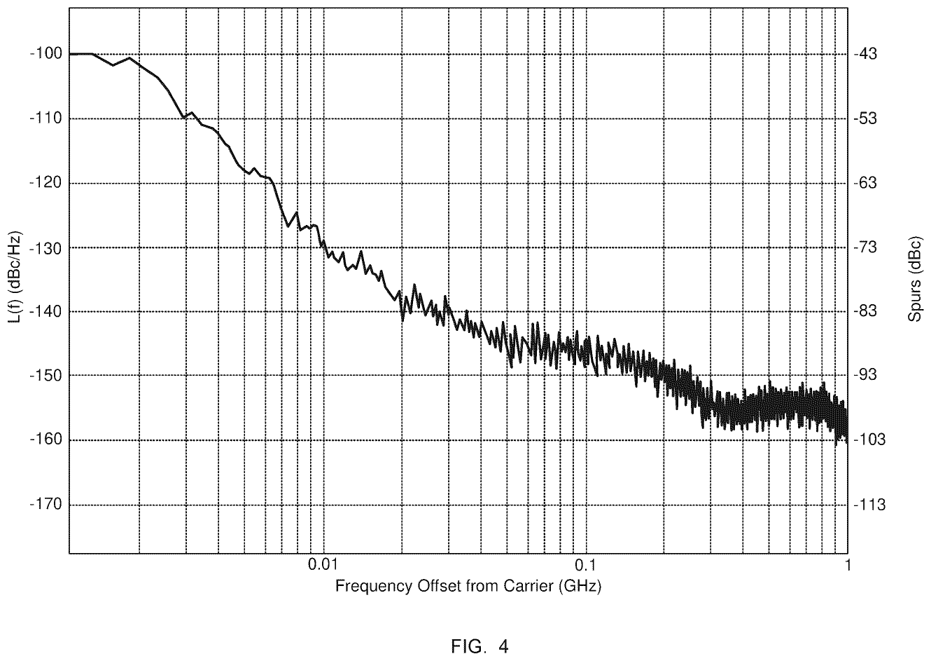

FIG. 4 is a graph of the phase noise for the same circuit, but where the simulation includes a 10% mismatch between up and down currents. This current mismatch reflects the effects of real-world PVT variations on currents from NMOS and PMOS transistors, as the charge pump generates both positive and negative current, responding to up and down pulses from the linear PFD when the reference and feedback phases are nearly equal (which the integral path ensures).

As FIGS. 3 and 4 show, a non-linear transfer of phase error to proportional correction degrades the in-band phase noise performance severely, due to folding of the feedback divider AZ modulator quantization noise. In fact, even if measures are taken to perfectly match the up and down currents, the linear phase detector introduces non-linearity in the zero-phase error region. See, e.g., Enrico Temporiti, “A 700-kHz Bandwidth ZA Fractional Synthesizer with Spurs Compensation and Linearization Techniques for WCDMA Applications,” IEEE Journal of Solid-State Circuits, Vol. 39, No. 9, September 2004, the disclosure of which is incorporated herein by reference in its entirety. Notably, Temporiti's technique of introducing phase shift through (pulsed) leakage, disclosed in the cited paper, is not possible in the circuit of FIG. 2, as the integral path defines the long-term PLL output phase such that the binary phase detector output will be zero on average.

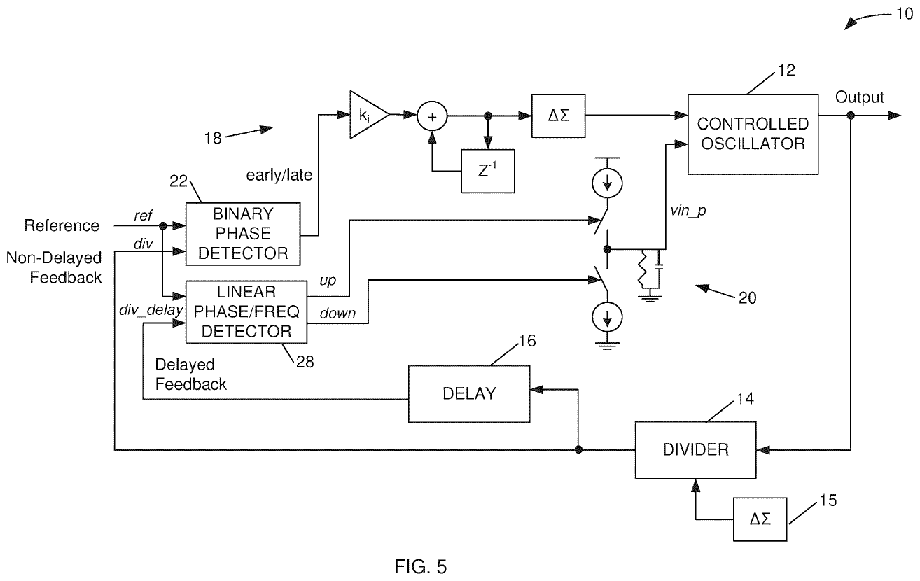

FIG. 5 depicts a dual path Phase Locked Loop (PLL) circuit 10 according to aspects of the present disclosure. The dual path PLL circuit 10 includes a controlled oscillator circuit 12, a frequency divider circuit 14, a delay circuit 16, an integral path of circuitry 18 implemented in the digital domain, and a proportional path of circuitry 20 implemented in the analog domain. The controlled oscillator circuit 12 is configured to generate a periodic output signal in response to frequency control inputs. The frequency divider circuit 14 configured to divide the periodic output signal by a divisor to generate a non-delayed feedback signal. In the aspect depicted, the divider circuit 14 is a fractional-N divider with a delta-sigma (AZ) modulator 15. The delay circuit 16 is configured to delay the non-delayed feedback signal, and hence generate a delayed feedback signal.

A binary phase detector 22 in the integral path 18 is configured to receive a periodic reference signal and the non-delayed feedback signal, and output a binary (i.e., digital) error signal indicative of a phase difference between the two signals. This digital phase error signal is integrated to generate a first frequency control signal for the controlled oscillator 12, to lock the long-term phase of the periodic output signal to the phase of the reference signal.

The proportional path of circuitry 20 includes a linear phase/frequency detector circuit 28 and a charge pump and filter. The linear phase detector circuit 28 of the proportional path 20 is configured to receive the periodic reference signal and the delayed feedback signal, and to generate phase error pulses. The charge pump and filter generate a second frequency control signal for the controlled oscillator 12 in response to the phase error pulses, to minimize a short-term phase error between the periodic output signal and the reference signal.

The delay in the feedback signal has the effect of linearizing the phase error to proportional correction transfer, by adding a fixed width to phase error pulses generated by the linear phase detector circuit 28. This pulse width addition moves the operating point of the charge pump from the zero crossing, where it must match PMOS and NMOS currents (difficult due to PVT variations), to a zone where only one of the transistors is supplying current.

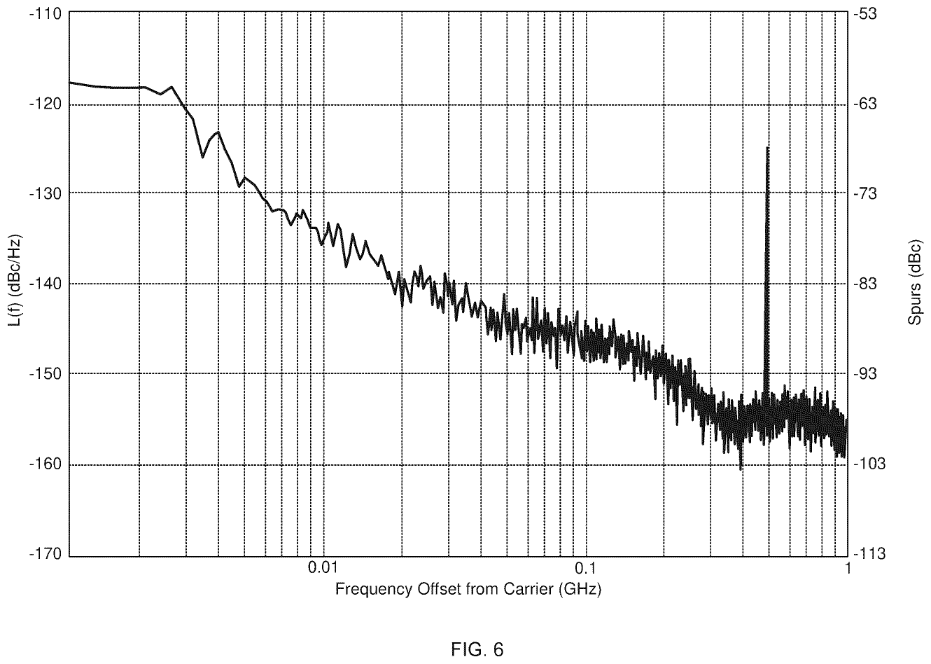

FIG. 6 plots the phase noise simulation result from the linearized structure of FIG. 5, where the charge pump positive and negative currents have a 10% mismatch. The in-band phase noise level is restored to the level of the simulation of the circuit of FIG. 2 with no charge pump current mismatch (as plotted in FIG. 3), using a perfectly linear phase error transfer in the proportional path 18. One drawback is that the reference signal spurious tone level has increased in this case, from below −95 to about −68 dBc. This is expected, as the longer duration pulses inject more reference frequency energy at the oscillator control input, and the pulses are being upconverted to sidebands around the oscillator frequency.

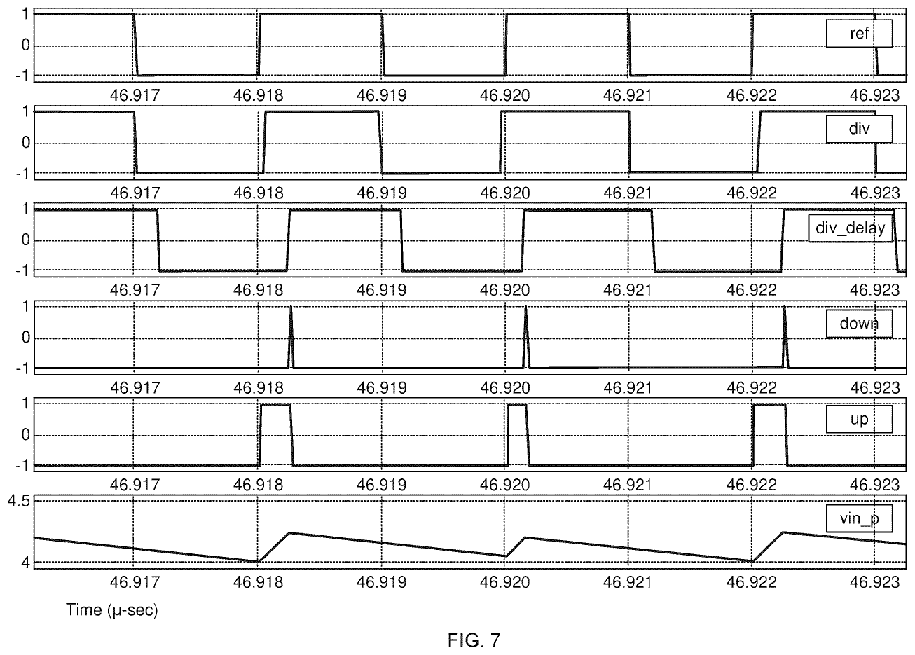

FIG. 7 plots various signals in the circuit of FIG. 5 (noted in FIG. 5 in italics). The bottom graph shows the transient response ripple of vin_p, the oscillator control output of the proportional path 20. Note that the ref (reference) and div (non-delayed divided feedback) signals are, on average, in phase. The div_delay (delayed feedback) signal being delayed causes the up pulses to vary in duration, whereas the down pulses are always the same duration—defined by the linear phase detector 28 reset delay (for a standard tristate PFD).

The reference frequency ripple on vin_p, which causes the spurious tones, is a result of the integral and proportional paths 18, 20 receiving different feedback signals, where the proportional path 20 is attempting to pull the phase in the same one direction once every reference cycle. In other aspects of the present disclosure, the proportional path 20 may strive for a desired phase in line with the integral path 18.

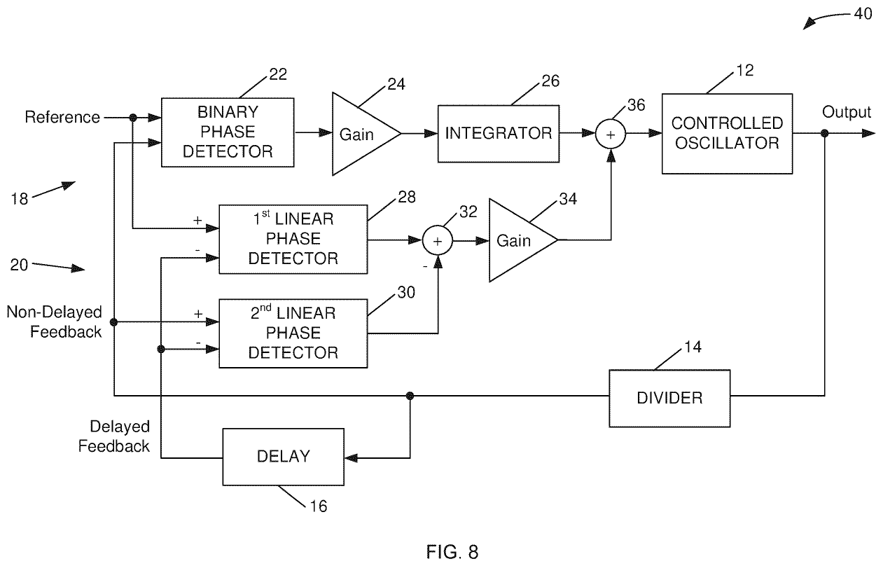

FIG. 8 depicts an architecture of a dual path PLL 40 including feedback signal delay compensation. As in the circuit of FIG. 5, the dual path PLL 40 includes a controlled oscillator circuit 12, a frequency divider circuit 14, a delay circuit 16, an integral path of circuitry 18, and a proportional path of circuitry 20. The proportional path 20 includes a first linear phase detector 28, which compares the phase of the reference signal to that of the delayed feedback signal, as previously described. The proportional path 20 also now includes a second linear phase detector 30, which compares the phase of the non-delayed feedback signal to that of the delayed feedback signal. The second linear phase detector 30 will thus generate pulses of a constant width, corresponding to the delay 16. Indeed, the pulses output by the second linear phase detector 30 are the same width as the pulse width added to the output of the first linear phase detector 28 by the delay injected into the feedback signal. The constant-width pulses output by the second linear phase detector 30 are subtracted from the output of the first linear phase detector 28 at the adder 32.

FIG. 8 depicts the controlled oscillator 12 control inputs from the integral path 18 and proportional path 20 being combined in an adder 32, and input to the controlled oscillator 12. In other aspects, a controlled oscillator 12 may have multiple control inputs, and the integral path 18 and proportional path 20 outputs drive the controlled oscillator 12 directly.

In some aspects, the integral path of circuitry 18 may comprise digital circuits, and the proportional path of circuitry 20 may comprise analog circuits. In this manner, the strengths of each implementation type may be leveraged.

FIG. 9 depicts an implementation according to one aspect, in which the divider 14 is a fractional-N divider, with a dela-sigma (AZ) modulator 15 providing the divisor. A simple delay circuit 16 is implemented by cascading D-type flip-flops, all clocked by the high frequency PLL 40 output. The integrator 26 in the integral path 18 may be implemented by Digital Signal Processing (DSP) or other known digital control. FIG. 9 depicts both the first and second linear phase detectors 28, 30 driving a charge pump and filter in the proportional path 20.

According to aspects of the present disclosure, as shown in FIGS. 8 and 9, the phase detection function is divided for the integral and proportional paths 18, 20. A delay 16 is injected into the feedback path for the proportional path 20. If this delay is sufficient, it results in phase errors of only one sign from the first linear (e.g., edge triggered) phase detector 28 during operation, which linearizes the transfer from phase error to proportional path correction. The second linear phase detector 30, comparing the delayed and non-delayed feedback paths, removes the effect of this delay on the phase error pulses, to minimize the reference signal spurious tone level.

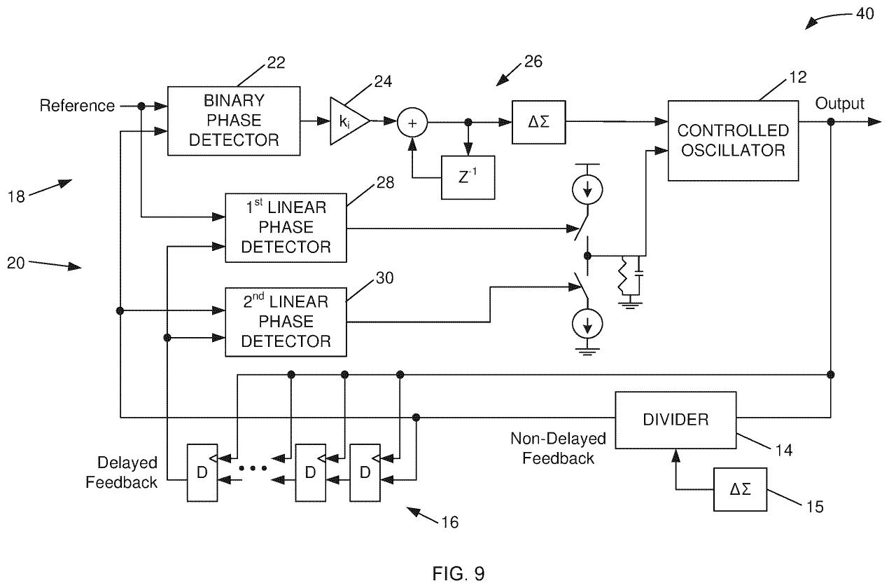

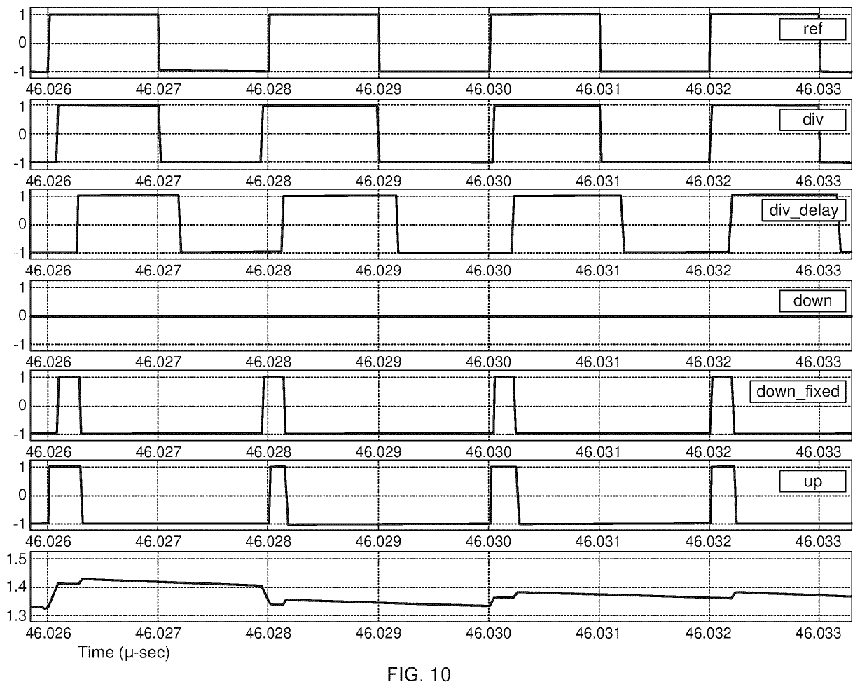

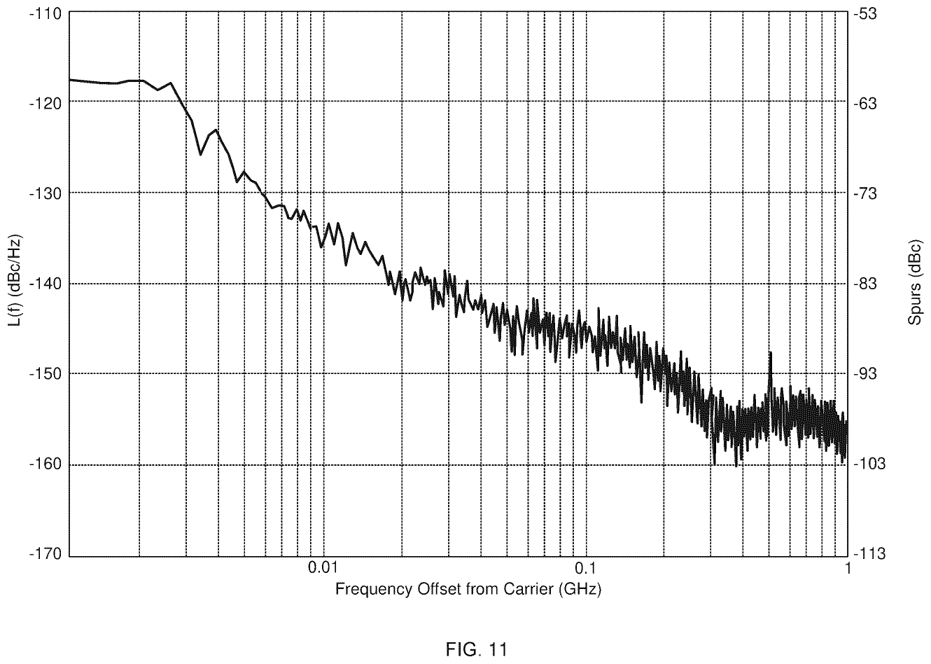

The circuit of FIG. 9 was simulated using CPP-sim, and the corresponding transient response is shown in the bottom plot of FIG. 10. The PLL output phase noise estimate from the simulation is shown FIG. 11. The second linear phase detector 30 improves the spur-level by more than 20 dB, but it is still at a higher level than in the ideal case of FIG. 2. The primary reason for this is that the two linear phase detectors 28, 30 contain circuitry (models, in the case of simulation) with different propagation delays. According to one aspect of the present disclosure, to further align the two linear phase detectors 28, 30, programmable fine tuning delays are implemented to minimize spurious energy.

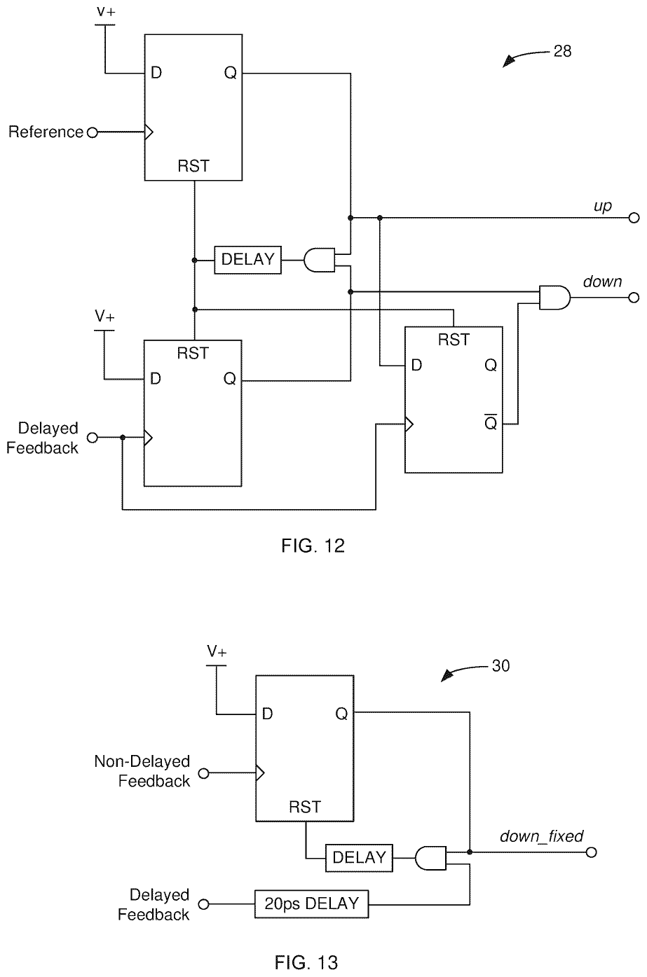

FIG. 12 depicts an implementation of the first linear phase detector circuit 28, which includes an additional register, as compared to a standard tristate PFD, to mask out reset pulses on the down signal, which are of no use in the locked condition. FIG. 13 depicts an implementation of the second linear phase detector circuit 30, which has one register less than a standard tristate PFD, and it is reset on a rising edge of the delayed feedback signal. The operation of the down and down_fixed signals of these circuits 28, 30 are shown in the graphs of FIG. 10. Those of skill in the art may readily devise variants on these circuits to address particular aspects, such as to improve timing matching.

FIG. 13 also depicts that the second linear phase detector 30 has a 20 ps delay imposed on the delayed feedback signal. This is to account for propagation delay mismatches between the first and second linear phase detector circuits 28, 30.

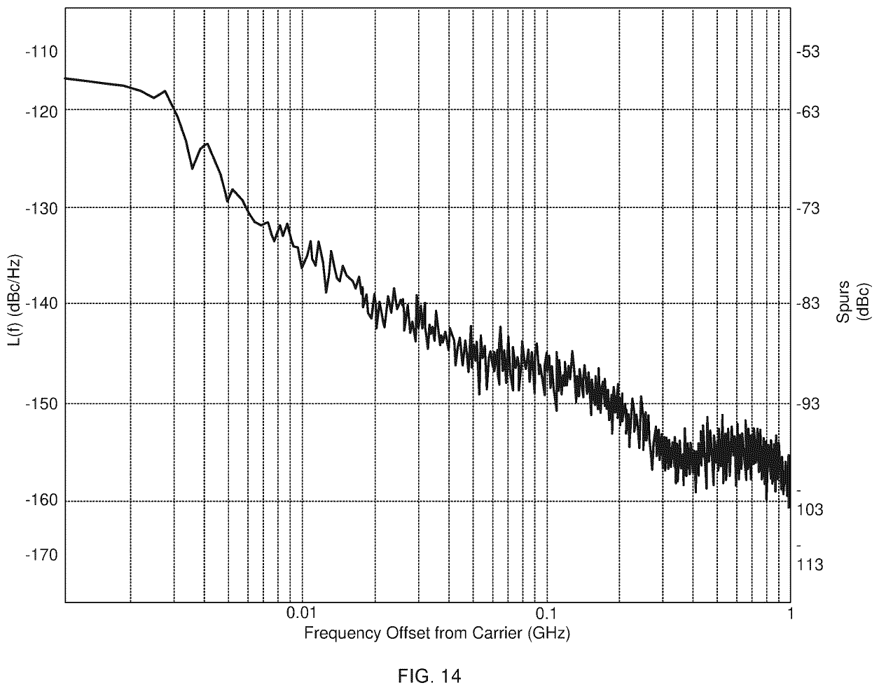

FIG. 14 plots the result of a simulation of the circuit of FIG. 9, using the circuits of FIGS. 12 and 13, with the 20 ps delay in the delayed feedback signal at the second linear phase detector 30. The reference spur is no longer visible in the phase noise plot of FIG. 14. For this simulation, the value of 20 ps for the delayed feedback signal was determined by trial and error. That is, the circuit was simulated with different values of delay, until the delay which minimized the reference spurs was found.

Splitting the control function of a PLL into two different circuit paths in implementation provides numerous advantages. As discussed above, it allows the two different phase control tasks—long-term phase locking to the reference signal and rapid mitigation of oscillator phase noise—to be addressed using the technology best suited to each respective task (e.g., digital and analog, respectively). Furthermore, separating the phase detection implementations of each path allows for linearization of the proportional path transfer function, without the use of a high accuracy TDC, as described herein.

However, separating the phase detection functions also introduces at least one drawback: the possibility of a slight phase alignment error remaining, causing the two paths 18, 20 have different desired output phase, notwithstanding the pulse width compensation provided by the second linear phase detector 30. This has two primary impacts. First, a varying control voltage in the proportional path 20 causes the charge pump to deviate from its optimal operating point. The charge pump operating at a non-optimal DC-voltage may cause the charge pump current to vary, affecting the PLL loop gain. Second, reference spur levels may be increased, due to the proportional path 20 attempting to pull the PLL 10, 40 out of the integral converged phase once every reference cycle. Reference spurs may cause reciprocal mixing in a receiver or violation of emissions masks in a transmitter.

The slight timing error giving rise to these divergent phase error outputs could possibly be independently determined, for each PLL 10, 40, by a calibration process. However, this would increase manufacturing complexity and costs, and the determined optimal delay may not hold over voltage and temperature variations in the field.

According to further aspects of the present disclosure, the voltage over the termination resistor of the proportional path 20 is low-pass filtered and input to a comparator. The comparator outputs one binary value if the voltage is positive and the other value if it is negative. Two different aspects of the present disclosure correct for the phase deviation between integral and proportional paths 18, 20, in different ways, both based on the comparator output.

In aspects where the PLL 10, 40 absolute output phase is allowed to vary, the output of the binary phase detector 22 in the integral path 18 is adjusted in a feedback loop striving for zero voltage over the resistor. For example, a control circuit may implement a binary search for the optimal value to add to the binary phase detector 22 output.

Alternatively, in aspects where the PLL 10, 40 output phase must be maintained, one of the proportional path feedback signals (e.g., delayed feedback signal) and the reference signal is delayed through the use of digitally controlled clock skew circuitry. Here also, a controller may employ a binary search, striving for zero voltage over the resistor.

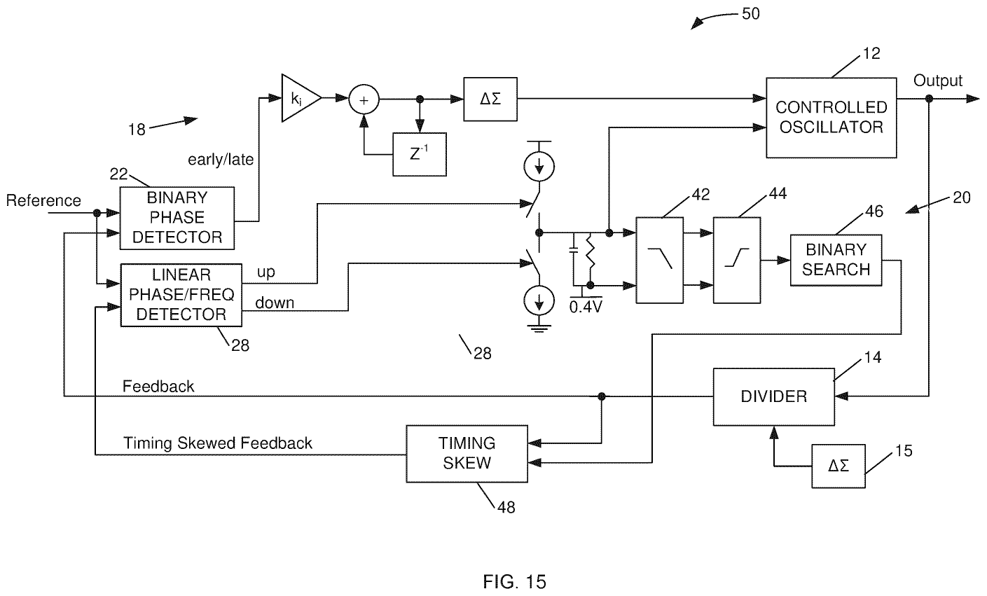

FIG. 15 depicts a dual path Phase Locked Loop (PLL) circuit 50 according to one aspect of the present disclosure. The dual path PLL circuit 50 includes a controlled oscillator circuit 12, a frequency divider circuit 14, an integral path of circuitry 18 implemented in the digital domain, and a proportional path of circuitry 20 implemented in the analog domain. The controlled oscillator circuit 12 is configured to generate a periodic output signal in response to frequency control inputs. The frequency divider circuit 14 configured to divide the periodic output signal by a divisor to generate a non-delayed feedback signal. In the aspect depicted, the divider circuit 14 is a fractional-N divider with a dela-sigma (ΔΣ) modulator 15.

A binary phase detector 22 compares the phases between a reference signal and a selected feedback signal (in this case the divided PLL output signal), and outputs a binary indication of the phase error to the integral path 18. A linear phase detector 22 similarly compares the phases between the reference signal and a selected feedback signal (in this case, a timing skewed divided PLL output signal), and outputs phase error (up/down) pulses to a charge pump and filter in the proportional path 18.

The voltage across the terminal resistor in the proportional path 20 is filtered by a low pass filter 42, and the filtered voltage is input to a comparator 44. The comparator outputs one value if the voltage is positive, and a different value if the voltage is negative. A binary search function 48 generates a control signal encoding a timing, and outputs the signal to a timing skew block 48. The timing skew block 48 adds a variable delay to the feedback signal, generating a timing skewed feedback signal. Both the feedback signal and the timing skewed feedback signal are fed back to the phase detectors 22, 28. In different aspects, the feedback signal is provided to one of the binary and linear phase detectors 22, 28, and the timing skewed feedback signal is provided to the other phase detector 28, 22, depending on whether the phase error timing of the integral path 18 or the proportional path 20 is to be adjusted. In either case, the binary search function 46 controls the timing skew block 48 to strive for zero voltage across the terminal resistor. This aligns the timing of the adjusted path 18, 20 (i.e., the path comparing the reference signal phase to that of the timing skewed feedback signal) with that of the non-adjusted path (i.e., the path comparing the reference signal phase to that of the feedback signal), to minimize reference spurs in the PLL 10 output due to the integral and proportional paths 18, 20 attempting to impose different phase corrections at each reference signal cycle. Note that the PLL circuit 50 of FIG. 15 does not include linearization of the proportional path phase error transfer function, and will accordingly exhibit high phase noise, compared to various other aspects disclosed herein. However, the timing skew control does minimize reference spurs, which may be sufficient for some applications.

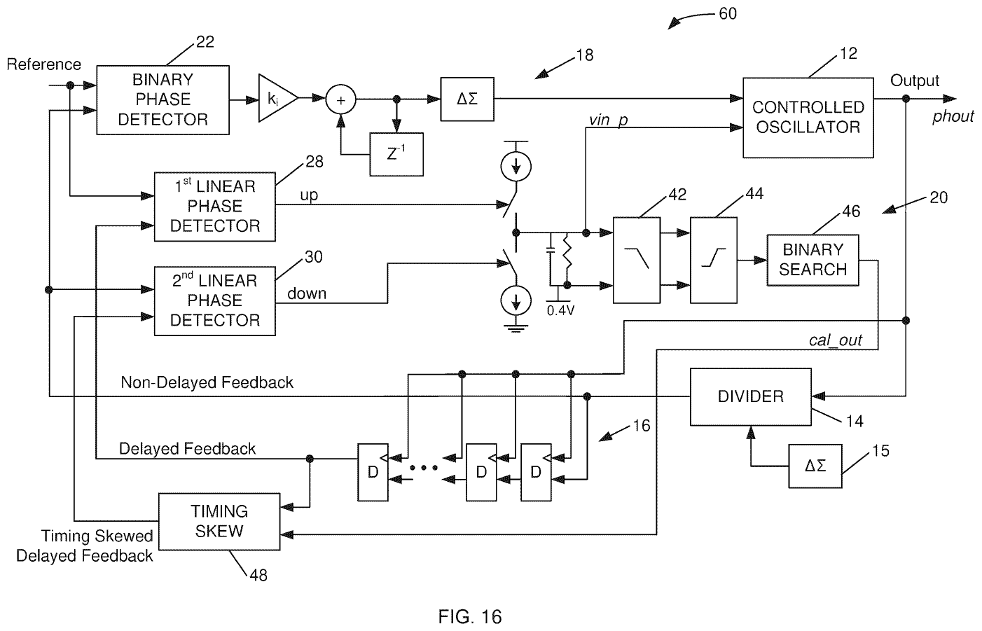

FIG. 16 depicts a dual path PLL circuit 60 according to one aspect of the present disclosure. The PLL circuit 60 includes the delay circuit 16, generating a delayed feedback signal to linearize the proportional path 20 transfer function, as described herein. The PLL circuit 60 further includes a second linear phase detector 30, to correct the pulse widths of phase error pulses generated by the first linear phase detector 28. In this respect, the PLL circuit 60 is similar to the PLL circuit 40 depicted in FIG. 9. Here, however, the proportional path 20 also includes a timing skew block 48, which automatically calculates a timing adjustment to the delayed feedback signal used by the second linear phase detector 30, to account for propagation delays between it and the first linear phase detector 28. The proportional path 20 circuitry does this by adjusting the binary search function 46 to strive for zero voltage across the terminal resistor of the loop filter. This circuit 60 was simulated in CPP-sim, with a 10% mismatch between positive and negative currents at the charge pump.

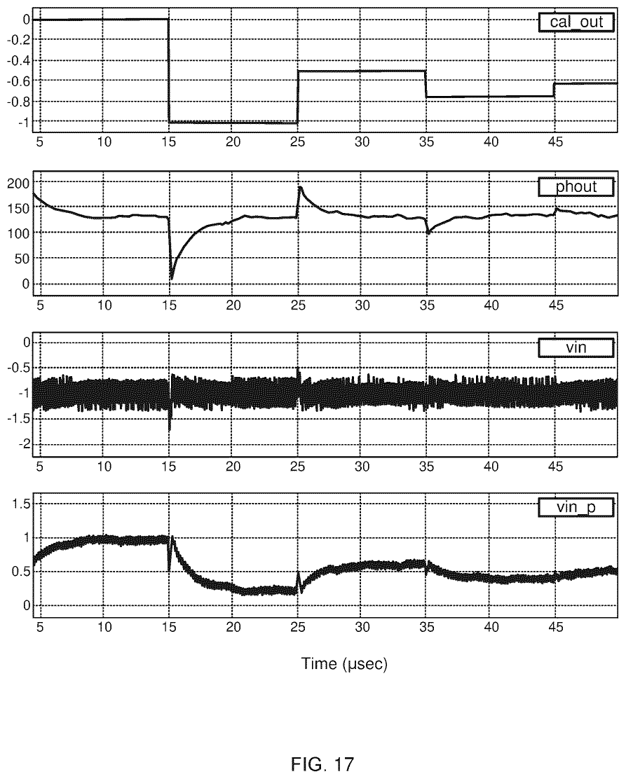

FIG. 17 depicts some of the transient signals from this simulation, and demonstrates convergence of the algorithm over five steps. The cal_out signal is the output of the binary search function 46; ph_out is a measure of the PLL 60 absolute output phase; vin is an equivalent total controlled oscillator tuning word; and vin_p is the voltage at one terminal of the proportional path 20 termination resistor. In this case, the other terminal was connected to 0.4V for the algorithm to converge towards a suitable voltage for the charge pump output. Accordingly, the graph of vin p converges to 0.4V, which is a voltage drop of zero across the resistor.

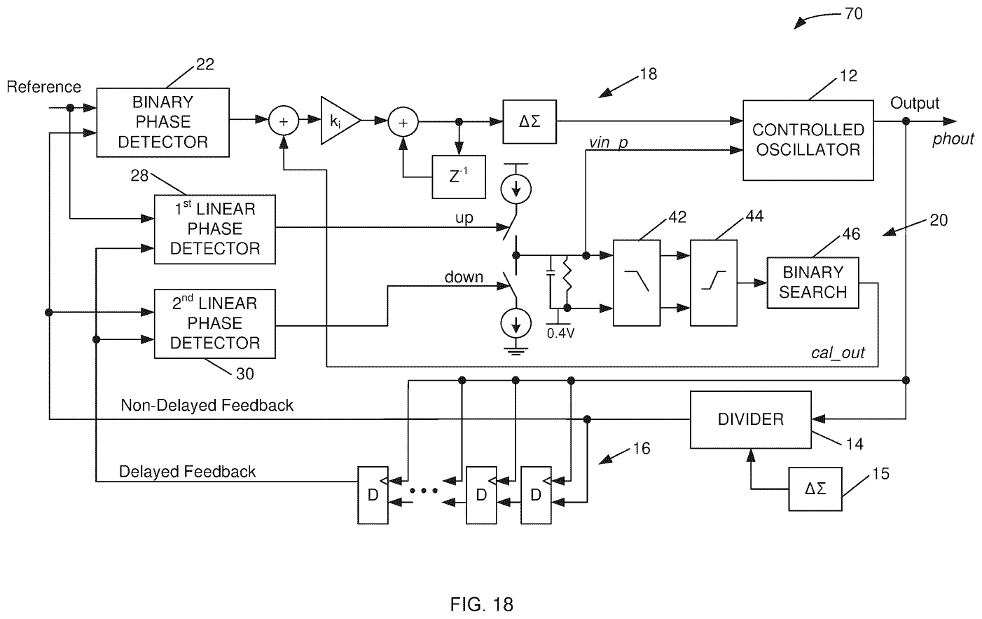

FIG. 18 depicts a dual path PLL circuit 70 according to another aspect of the present disclosure. The PLL circuit 70 includes the delay circuit 16, generating a delayed feedback signal to linearize the proportional path 20 transfer function, and a second linear phase detector 30, to correct the pulse widths of phase error pulses generated by the first linear phase detector 28. The PLL circuit 70 also includes a low pass filter 42 filtering the voltage across the termination resistor of the proportional path 20, a comparator 44, and binary search function 46. In this aspect, however, the output cal_out of the binary search function 46 is directly added to the output of the binary phase detector 22 in the integral path 18. As such, it directly alters the phase phout of the PLL circuit 70 output. The binary search function 46 seeks a value of cal_out resulting in zero voltage across the termination resistor, thus aligning the phase corrections generated by the integral and proportional paths 18, 20.

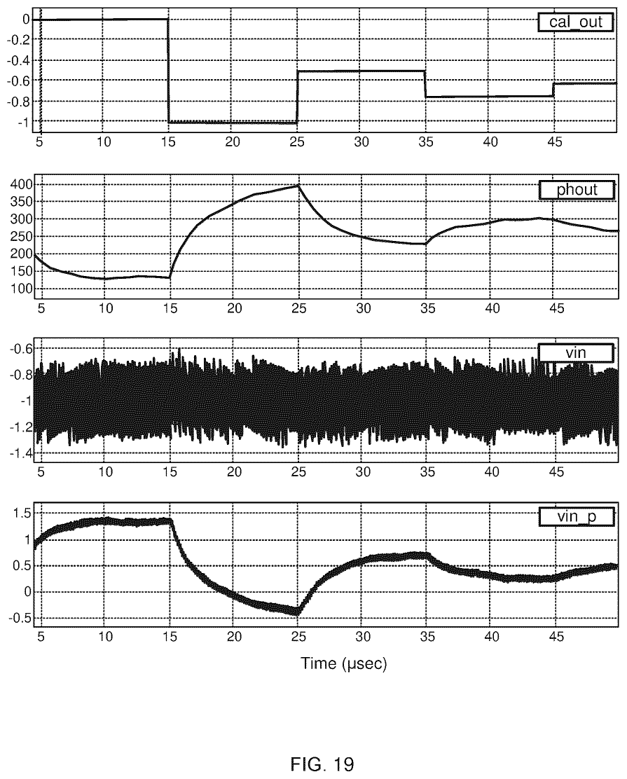

FIG. 19 depicts the signals during simulation. Note that the PLL circuit 70 output phase phout is directly altered by the cal_out output of the binary search function 46.

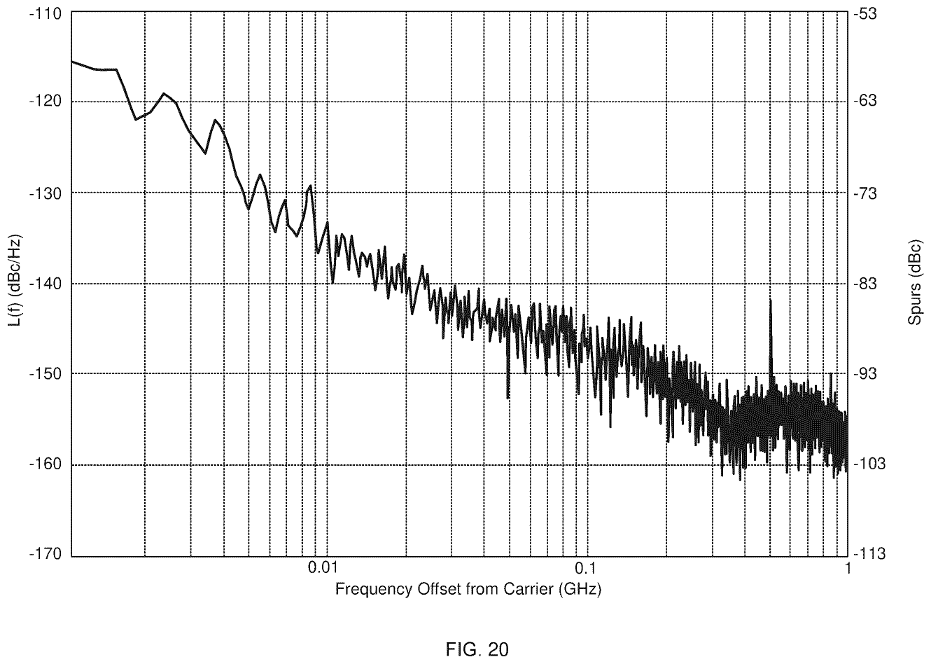

FIG. 20 depicts the phase noise of simulations of the PLL circuit 70 of FIG. 18, wherein the charge pump has a 10% mismatch between positive and negative currents, and wherein the integral and proportional path 18, 20 timing matching circuits 42, 44, 46 are inactive. This plot shows a prominent reference spur.

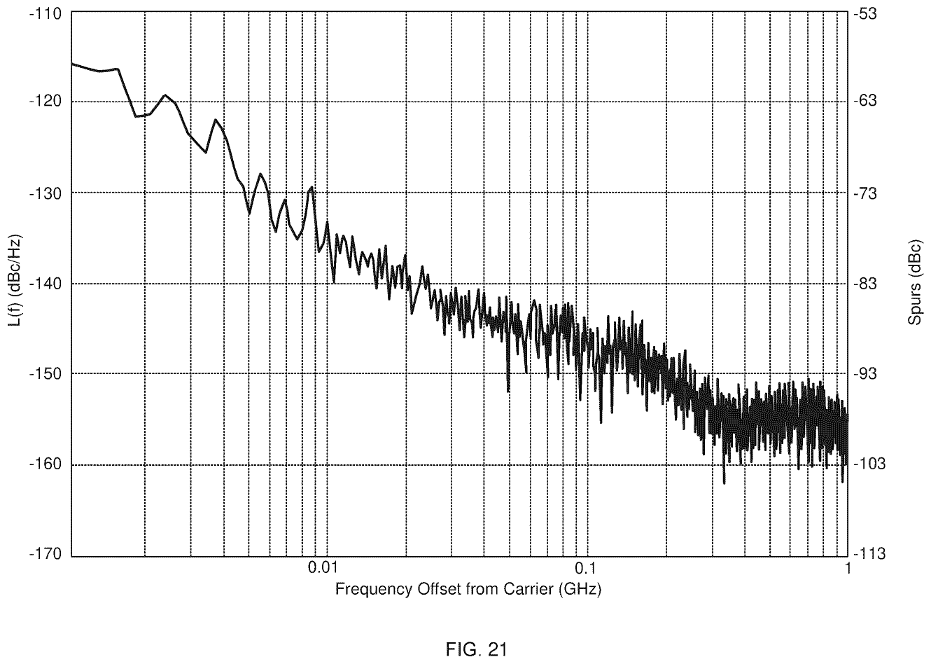

FIG. 21 depicts the phase noise of simulations of the same PLL circuit 70 with the integral and proportional path 18, 20 timing matching circuits 42, 44, 46 active, adjusting the output phase phout of the PLL circuit 70 to match that corrected by the proportional path 20—that is, striving for zero voltage across the proportional path 20 terminal resistor. The reference spur vanishes in the phase noise floor.

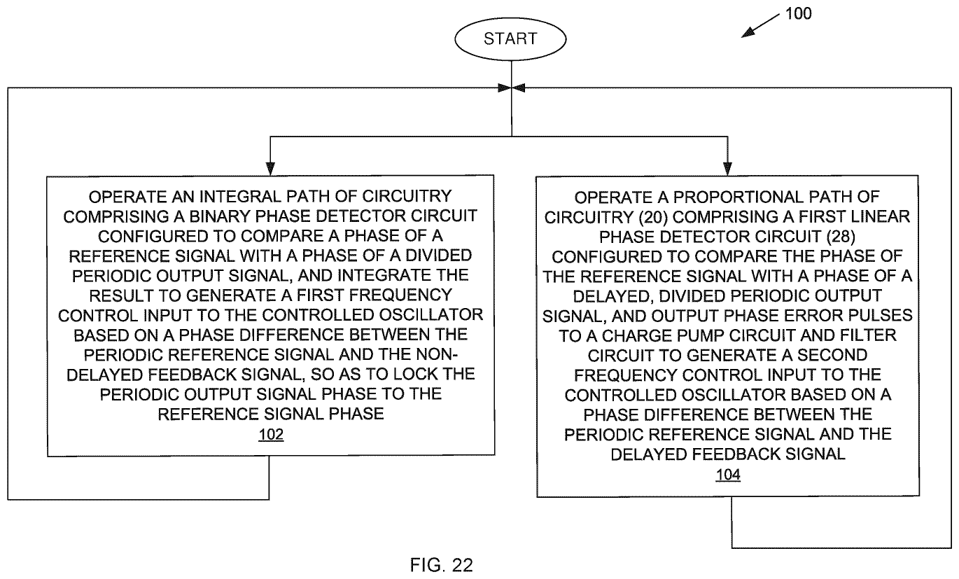

FIG. 22 depicts the steps in a method 100 of generating a periodic output signal, the method 100 being performed in a dual path PLL 10, 40, 60, 70 comprising a controlled oscillator 12 configured to generate a periodic output signal in response to frequency control inputs. An integral path of circuitry 18 is operated (block 102). The integral path 18 comprises a binary phase detector circuit 22 configured to compare a phase of a reference signal with a phase of a divided periodic output signal. The integral path 18 integrates the result to generate a first frequency control input to the controlled oscillator 12 to lock the periodic output signal phase to the reference signal phase. A proportional path of circuitry 20 is also operated (block 104). The proportional path 20 comprises a first linear phase detector circuit 28 configured to compare the phase of the reference signal with a phase of a delayed, divided periodic output signal, and output phase error pulses to a charge pump circuit and filter circuit to generate a second frequency control input to the controlled oscillator to mitigate phase noise in the periodic output signal. The delay of the delayed, divided periodic output signal increases a width of phase error pulses output by the linear phase detector 28, such that the charge pump circuit provides only positive or negative current to the filter circuit.

As indicated by the arrows, the steps 102, 104 of the method 100 are performed in parallel, and repeat. That is, both steps 102 and 104 are continuously performed by the PLL 10, 40, 60, 70. For example, both the binary phase detector 22 and linear phase detector 28 compare the phase of their input signal each cycle of the periodic output signal, and the respective integral and proportional paths 18, 20 generate frequency correction signals for the controlled oscillator 12 every cycle.

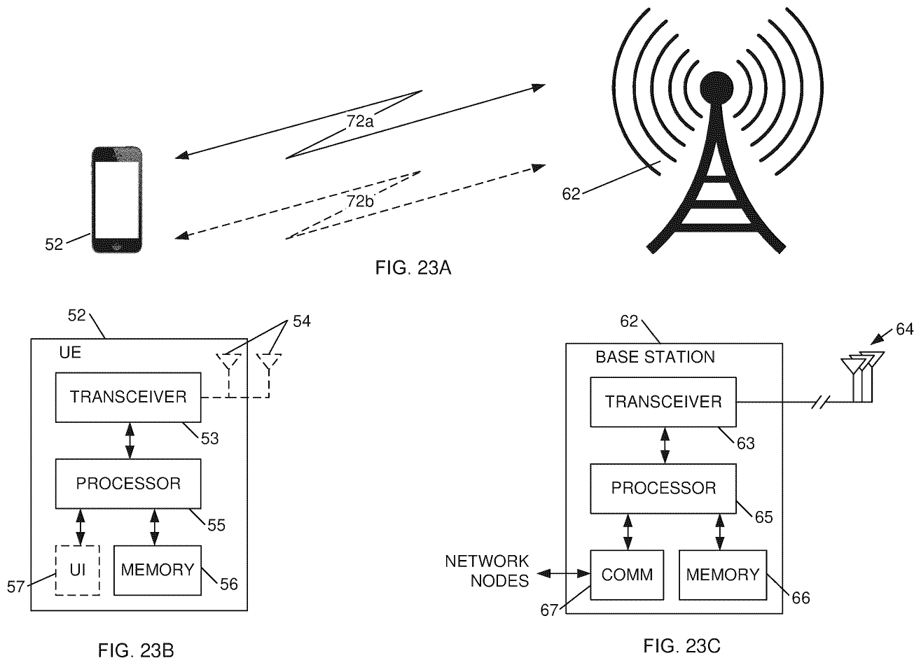

FIG. 23A is a diagram of communication over the air interface of a wireless communication network. A User Equipment (UE) 52, such as a smartphone, receives and transmits modulated Radio Frequency (RF) signals, over one or more antennas, from and to a base station 62, such as an LTE eNB or an NR gNB. The communication is via at least one RF signal 72a between the UE 52 and base station 62. In some aspects, one or both of the UE 52 and base station 72 may deploy multiple antennas, and the communication occurs over a plurality of RF signals 72a, 72b, etc. In this case, the UE 52 and base station 62 may employ Multiple Input, Multiple Output (MIMO) techniques, such as spatial diversity and/or spatial multiplexing, to increases robustness against fading or co-channel interference, and to improve bitrates. The RF signals 72a, 72b may be in the millimeter wave frequency bands. Although only two RF signals 72a, 72b are shown, in general MIMO transmissions may comprise multiple separate transmissions (e.g., 2, 4, 8, . . . , 128, or more). At each of the UE 52 and base station 62, multiple transceivers, associated with the multiple antennas, receive and transmit RF signals. These transceivers require multiple Local Oscillator (LO) signals for accurate frequency conversion. Additionally or alternatively, one or both of the UE 52 and base station 62 may implement beamforming, wherein the directionality of Tx or Rx antenna beams is increased and controlled by controlling the phase of multiple antenna elements in a phased array antenna. In this application also, multiple transceivers each require an LO signal.

FIG. 23B is a block diagram of the UE 52 of FIG. 23A. As used herein, the term UE may refer to a user-operated telephony terminal, a machine-to-machine (M2M) device, a machine-type communications (MTC) device, a Narrowband Internet of Things (NB-IoT) device (in particular a UE implementing the 3GPP standard for NB-IoT), etc. A UE 52 may also be referred to as a radio device, a radio communication device, a wireless communication device, a wireless terminal, or simply a terminal—unless the context indicates otherwise, the use of any of these terms is intended to include device-to-device UEs or devices, machine-type devices or devices capable of machine-to-machine communication, sensors equipped with a radio network device, wireless-enabled table computers, mobile terminals, smartphones, laptop-embedded equipped (LEE), laptop-mounted equipment (LME), USB dongles, wireless customer-premises equipment (CPE), and the like.

The UE 52 transmits and receives RF signals (including MIMO signals), which may for example be in the millimeter wave frequency bands, on at least one antenna 54, which may be internal or external, as indicated by dashed lines. The RF signals are generated and received by one or more transceiver circuits 53. At least one transceiver circuit 53 includes a dual path PLL circuit 10, 40, 50, 60, 70 according to aspects of the present disclosure, such as to generate LO signals. The transceiver circuits 53, as well as other components of the UE 52, are controlled by processing circuitry 55. Memory 56 operatively connected to (or internal to) the processing circuitry 53 stores software in the form of computer instructions operative to cause the processing circuitry 55 to execute various procedures. A user interface 57 may include output devices such as a display and speakers (and/or a wired or wireless connection to audio devices such as ear buds), and/or input devices such as buttons, a keypad, a touchscreen, and the like. As indicated by the dashed lines, the user interface 57 may not be present in all UEs 52; for example, UEs 52 designed for Machine Type Communications (MTC) such as Internet of Things (IoT) devices, may perform dedicated functions such as sensing/measuring, monitoring, meter reading, and the like, and may not have any user interface 57 features.

FIG. 23C is a block diagram of the base station 62 of FIG. 23A. A base station 62—known in various network implementations as a Radio Base Station (RBS), Base Transceiver Station (BTS), Node B (NB), enhanced Node B (eNB), Next Generation Node B (gNB), or the like—is a node of a wireless communication network that implements a Radio Access Network (RAN) in a defined geographic area called a cell, by providing radio transceivers to communicate wirelessly with a plurality of UEs 52.

The base station 62 transmits and receives RF signals (including MIMO signals), which may for example be in the millimeter wave frequency bands, on a plurality of antennas 64. As indicated by the broken line, the antennas 64 may be located remotely from the base station 62, such as on a tower or building. The RF signals are generated and received by one or more transceiver circuits 63. At least one transceiver circuit 63 includes a dual path PLL circuit 10, 40, 50, 60, 70 according to aspects of the present disclosure, such as to generate a LO signal. The transceiver circuits 63, as well as other components of the base station 62, are controlled by processing circuitry 65. Memory 66 operatively connected to the processing circuitry 65 stores instructions operative to cause the processing circuitry 65 to execute various procedures. Although the memory 66 is depicted as being separate from the processing circuitry 65, those of skill in the art understand that the processing circuitry 65 includes internal memory, such as a cache memory or register file. Those of skill in the art additionally understand that virtualization techniques allow some functions nominally executed by the processing circuitry 65 to actually be executed by other hardware, perhaps remotely located (e.g., at a data center in the so-called “cloud”). Communication circuitry 67 provides one or more communication links to one or more other network nodes, propagating communications to and from UEs 52, from and to other network nodes or other networks, such as telephony networks or the Internet.

In all embodiments, the processing circuitry 53, 63 may comprise any sequential state machine operative to execute machine instructions stored as machine-readable computer programs in memory 56, 66, such as one or more hardware-implemented state machines (e.g., in discrete logic, FPGA, ASIC, etc.); programmable logic together with appropriate firmware; one or more stored-program, general-purpose processors, such as a microprocessor or Digital Signal Processor (DSP), together with appropriate software; or any combination of the above.

In all embodiments, the memory 56, 66 may comprise any non-transitory machine-readable media known in the art or that may be developed, including but not limited to magnetic media (e.g., floppy disc, hard disc drive, etc.), optical media (e.g., CD-ROM, DVD-ROM, etc.), solid state media (e.g., SRAM, DRAM, DDRAM, ROM, PROM, EPROM, Flash memory, solid state disc, etc.), or the like.

In all embodiments, the transceiver circuits 53, 63 are operative to communicate with one or more other transceivers via a Radio Access Network (RAN) according to one or more communication protocols known in the art or that may be developed, such as IEEE 802.xx, CDMA, WCDMA, GSM, LTE, UTRAN, WiMax, NB-IoT, or the like. The transceiver 53, 63 implements transmitter and receiver functionality appropriate to the RAN links (e.g., frequency allocations and the like). The transmitter and receiver functions may share circuit components and/or software, or alternatively may be implemented separately.

In all embodiments, the communication circuitry 67 may comprise a receiver and transmitter interface used to communicate with one or more other nodes over a communication network according to one or more communication protocols known in the art or that may be developed, such as Ethernet, TCP/IP, SONET, ATM, IMS, SIP, or the like. The communication circuits 67 implement receiver and transmitter functionality appropriate to the communication network links (e.g., optical, electrical, and the like). The transmitter and receiver functions may share circuit components and/or software, or alternatively may be implemented separately.

Those skilled in the art will also appreciate that embodiments herein further include corresponding computer programs.

A computer program comprises instructions which, when executed on at least one processor of an apparatus, cause the apparatus to carry out any of the respective processing described above. A computer program in this regard may comprise one or more code modules corresponding to the means or units described above.

Embodiments further include a carrier containing such a computer program. This carrier may comprise one of an electronic signal, optical signal, radio signal, or computer readable storage medium.

In this regard, embodiments herein also include a computer program product stored on a non-transitory computer readable (storage or recording) medium and comprising instructions that, when executed by a processor of an apparatus, cause the apparatus to perform as described above.

Embodiments further include a computer program product comprising program code portions for performing the steps of any of the embodiments herein when the computer program product is executed by a computing device. This computer program product may be stored on a computer readable recording medium.

Aspects of the present disclosure present numerous advantages over PLLs known in the art. The dual path enables high phase stability in a fractional-N PLL without the need for highly accurate TDCs. The analog edge triggered phase error detection in the proportional path enables a low-complexity, low-noise implementation for communication systems where higher order modulation schemes require low Error Vector Magnitude (EVM). Using a delay of the feedback signal to shift the proportional path phase error detection out from a region where phase errors of both signs are detected enables a highly linear phase error to proportional correction transfer function. High linearity and low noise for the proportional correction in a PLL enables excellent in-band phase noise performance in a fractional-N PLL. By compensating for increased pulse widths moving out from the zero-phase error region, the reference frequency oscillator control ripple is reduced, and thus spurious tones in the output spectrum are suppressed. Additionally, avoiding very narrow phase error pulses enables optimization of the charge pump for noise, rather than speed, which further improves PLL phase noise performance.

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. The steps of any methods disclosed herein do not have to be performed in the exact order disclosed, unless a step is explicitly described as following or preceding another step and/or where it is implicit that a step must follow or precede another step. Any feature of any of the aspects disclosed herein may be applied to any other aspect, wherever appropriate. Likewise, any advantage of any of the aspects may apply to any other aspects, and vice versa. Other objectives, features, and advantages of the enclosed aspects will be apparent from the description.

The term “unit” may have conventional meaning in the field of electronics, electrical devices and/or electronic devices and may include, for example, electrical and/or electronic circuitry, devices, modules, processors, memories, logic solid state and/or discrete devices, computer programs or instructions for carrying out respective tasks, procedures, computations, outputs, and/or displaying functions, and so on, such as those that are described herein. As used herein, the term “configured to” means set up, organized, adapted, or arranged to operate in a particular way; the term is synonymous with “designed to.” As used herein, the term “substantially” means nearly or essentially, but not necessarily completely; the term encompasses and accounts for mechanical or component value tolerances, measurement error, random variation, and similar sources of imprecision.

Some of the aspects contemplated herein are described more fully with reference to the accompanying drawings. Other aspects, however, are contained within the scope of the subject matter disclosed herein. The disclosed subject matter should not be construed as limited to only the aspects set forth herein; rather, these aspects are provided by way of example to convey the scope of the subject matter to those skilled in the art.

The present disclosure may, of course, be carried out in other ways than those specifically set forth herein without departing from essential characteristics of the disclosure. The present aspects are to be considered in all respects as illustrative and not restrictive, and all changes coming within the meaning and equivalency range of the appended claims are intended to be embraced therein.

1-23. (canceled)

24. A dual path Phase Locked Loop (PLL) circuit configured to minimize phase error between a periodic output signal and a reference signal, comprising:
a controlled oscillator circuit configured to generate the periodic output signal in response to frequency control inputs;
a frequency divider circuit configured to divide the periodic output signal by a divisor to generate a non-delayed feedback signal;
a delay circuit configured to delay the non-delayed feedback signal and generate a delayed feedback signal;
an integral path of circuitry configured to receive the periodic reference signal and the non-delayed feedback signal, and to generate a first frequency control signal for the controlled oscillator based on a phase difference between the periodic reference signal and the non-delayed feedback signal, so as to lock the phase of the periodic output signal to the phase of the reference signal; and
a proportional path of circuitry configured to receive the periodic reference signal and the delayed feedback signal, and to generate a second frequency control signal for the controlled oscillator based on a phase difference between the periodic reference signal and the delayed feedback signal.

25. The PLL circuit of claim 24 wherein the divisor of the frequency divider circuit is an integer.

26. The PLL circuit of claim 24, wherein the divisor of the frequency divider circuit includes a fractional component.

27. The PLL circuit of claim 24, wherein the integral path of circuitry includes a binary phase detector configured to output an indication of a difference in phase between the reference signal and the non-delayed feedback signal.

28. The PLL circuit of claim 27, wherein the integral path of circuitry comprises digital circuitry.

29. The PLL circuit of claim 24, wherein the proportional path of circuitry comprises a first edge triggered phase detector configured to receive the reference signal and the delayed feedback signal, and to output a plurality of phase error pulses, a width of each phase error pulse indicating at least a difference in phase between the reference signal and the delayed feedback signal.

30. The PLL circuit of claim 29, wherein the proportional path of circuitry comprises analog circuitry.

31. The PLL circuit of claim 29, wherein the proportional path of circuitry further comprises:
a charge pump connected to the output of the first phase detector; and
a filter connected to the output of the charge pump and configured to output a proportional frequency correction signal to the controlled oscillator;
wherein the phase error pulses cause the charge pump to output one of positive and negative current, but not both, to the filter.

32. The PLL circuit of claim 29 wherein a phase error to proportional frequency correction transfer function exhibits greater linearity than a corresponding transfer function in a PLL circuit without the delay of the feedback signal.

33. The PLL circuit of claim 31, wherein the proportional path of circuitry is further configured to receive the non-delayed feedback signal, and wherein the proportional path of circuitry further comprises:
a second edge triggered phase detector configured to receive the non-delayed feedback signal and the delayed feedback signal, and to output a plurality of phase error pulses, a width of each phase error pulse indicating a difference in phase between the non-delayed feedback signal and the delayed feedback signal.

34. The PLL circuit of claim 33, further comprising an adder configured to combine phase error pulses output by the first and second phase detectors, and wherein the width of phase error pulses output by the first phase detector is effectively reduced by the width of phase error pulses output by the second phase detector.

35. The PLL circuit of claim 33, wherein the second phase detector outputs only phase error pulses indicating that the non-delayed feedback signal leads the delayed feedback signal in phase.

36. The PLL circuit of claim 33, wherein one of the first and second phase detectors includes an added propagation delay configured to equalize the frequency correction signals output by the integral and proportional paths of circuitry.

37. The PLL circuit of claim 33, further comprising a timing skew feedback loop in the proportional path of circuitry, comprising:
a low pass filter connected across a terminal resistor of the filter;
a comparator connected to the low pass filter and configured to output a binary indication of a polarity of a low-pass filtered voltage across the terminal resistor of the filter; and
a control circuit configured to generate a timing skew control signal in response to the binary indication of polarity;
wherein the control circuit is configured to strive for zero voltage across the terminal resistor of the filter.

38. The PLL circuit of claim 37, wherein the control circuit implements a binary search algorithm.

39. The PLL circuit of claim 37, further comprising:
a timing skew circuit configured to add an incremental delay to the delayed feedback signal, in response to the timing skew control signal output by the control circuit; and
wherein the second edge triggered phase detector in the proportional path of circuitry is configured to receive the non-delayed feedback signal and the delayed feedback signal with also the incremental delay of the timing skew circuit.

40. The PLL circuit of claim 37, wherein the timing skew control signal is added to the output of the binary phase detector in the integral path of circuitry.

41. A dual path Phase Locked Loop (PLL) circuit configured to minimize phase error between a periodic output signal and a reference signal, characterized by:
a controlled oscillator circuit configured to generate the periodic output signal in response to frequency control inputs;
a frequency divider circuit configured to divide the periodic output signal by a divisor to generate a feedback signal;
an integral path of circuitry configured to receive the periodic reference signal and one of the feedback signal and a timing-skewed feedback signal, and to generate a first frequency control signal for the controlled oscillator based on a phase difference between the periodic reference signal and the non-delayed feedback signal, so as to lock the phase of the periodic output signal to the phase of the reference signal, wherein the integral path of circuitry comprises a binary phase detector; and
a proportional path of circuitry configured to receive the periodic reference signal and one of the feedback signal and the timing-skewed feedback signal, and to generate a second frequency control signal for the controlled oscillator based on a phase difference between the periodic reference signal and the delayed feedback signal, wherein the proportional path of circuitry comprises a linear phase detector;
a charge pump connected to an output of the linear phase detector;
a filter connected to the output of the charge pump and configured to output a proportional frequency correction signal to the controlled oscillator;
a low pass filter connected across a terminal resistor of the filter;
a comparator connected to the low pass filter and configured to output a binary indication of a polarity of a low-pass filtered voltage across the terminal resistor of the filter; and
a control circuit configured to generate a timing skew control signal in response to the binary indication of polarity;
wherein the control circuit is configured to strive for zero voltage across the terminal resistor of the filter; and
wherein the timing skew control signal is added to the output of the binary phase detector, or controls an incremental delay added by a timing skew circuit to the feedback signal input to the linear phase detector.

42. A method, in a dual path Phase Locked Loop (PLL) comprising a controlled oscillator configured to generate a periodic output signal in response to frequency control inputs, of generating the periodic output signal, comprising:
operating an integral path of circuitry comprising a binary phase detector circuit configured to compare a phase of a reference signal with a phase of a divided periodic output signal, and integrate the result to generate a first frequency control input to the controlled oscillator based on a phase difference between the periodic reference signal and the non-delayed feedback signal, so as to lock the periodic output signal phase to the reference signal phase; and
operating a proportional path of circuitry comprising a first linear phase detector circuit configured to compare the phase of the reference signal with a phase of a delayed, divided periodic output signal, and output phase error pulses to a charge pump circuit and filter circuit to generate a second frequency control input to the controlled oscillator based on a phase difference between the periodic reference signal and the delayed feedback signal;
wherein the delay of the delayed, divided periodic output signal increases a width of phase error pulses output by the linear phase detector such that the charge pump circuit provides only positive or negative current to the filter circuit.

43. The method of claim 42, wherein operating the proportional path further comprises delay compensating the phase error pulses by combining them with pulses output by a second linear phase detector circuit configured to compare phases of the divided periodic output signal and the delayed, divided periodic output signal.

44. The method of claim 43 further comprising adjusting a timing of one of the integral and proportional paths so as to strive for zero voltage across a terminal resistor of the filter circuit in the proportional path of circuitry.

45. A base station operative in a wireless communication network, comprising:
processing circuitry; and
transceiver circuitry operatively connected to the processing circuitry, the transceiver circuitry including at least one dual path Phase Locked Loop (PLL), PLL configured to minimize phase error between a periodic output signal and a reference signal, characterized by
a controlled oscillator circuit configured to generate the periodic output signal in response to frequency control inputs;
a frequency divider circuit configured to divide the periodic output signal by a divisor to generate a non-delayed feedback signal;
a delay circuit configured to delay the non-delayed feedback signal and generate a delayed feedback signal;
an integral path of circuitry configured to receive the periodic reference signal and the non-delayed feedback signal, and to generate a first frequency control signal for the controlled oscillator based on a phase difference between the periodic reference signal and the non-delayed feedback signal, so as to lock the phase of the periodic output signal to the phase of the reference signal; and
a proportional path of circuitry configured to receive the periodic reference signal and the delayed feedback signal, and to generate a second frequency control signal for the controlled oscillator based on a phase difference between the periodic reference signal and the delayed feedback signal.

46. User Equipment (UE), UE operative in a wireless communication network, comprising:
processing circuitry; and
transceiver circuitry operatively connected to the processing circuitry, the transceiver circuitry including at least one dual path Phase Locked Loop (P, PLL configured to minimize phase error between a periodic output signal and a reference signal, characterized by
a controlled oscillator circuit configured to generate the periodic output signal in response to frequency control inputs;
a frequency divider circuit configured to divide the periodic output signal by a divisor to generate a non-delayed feedback signal;
a delay circuit configured to delay the non-delayed feedback signal and generate a delayed feedback signal;
an integral path of circuitry configured to receive the periodic reference signal and the non-delayed feedback signal, and to generate a first frequency control signal for the controlled oscillator based on a phase difference between the periodic reference signal and the non-delayed feedback signal, so as to lock the phase of the periodic output signal to the phase of the reference signal; and
a proportional path of circuitry configured to receive the periodic reference signal and the delayed feedback signal, and to generate a second frequency control signal for the controlled oscillator based on a phase difference between the periodic reference signal and the delayed feedback signal.
